(19) United States
(12) Patent Application Publication
(10) Pub. No.: US 2004/0147136 A1
(43) Pub. Date: Jul. 29, 2004

(54) Method for making the gate dielectric layer by oxygen radicals and hydroxyl radicals mixture

(75) Inventors: Cheng-Shun Chen, Hsin-Chu (TW); Yun-Chi Yang, Hsin-Chu (TW); Shu-Ya Hsu, Yun-Lin (TW); Wei-Wen Chen, Hsin-Chu (TW); June-Min Yao, Hsin-Chu (TW)

Correspondence Address: LOWE HAUPTMAN GILMAN, & BERNER, LLP, Suite 310, 1700 Diagonal Road, Alexandria, VA, 22314, US

(73) Assignee: Macronix International Co., Ltd.

(21) Appl. No.: 10/352,920

(22) Filed: Jan. 29, 2003

(51) Int. Cl. H01L 21/336; H01L 21/31; H01L 21/469

(52) U.S. Cl. 438/778; 438/786; 438/287

(57) ABSTRACT

This invention relates to a method for making the gate dielectric layer, more particularly, to the method for making the interface between the gate dielectric layer and silicon substrate by using oxygen radicals and hydroxyl radicals. In the method, we send the wafers, which has passed through the cleaning process for the silicon substrate, to the chamber at first and then transmit the first reaction gas, which comprises the nitric monoxide and the oxygen or comprises the nitric monoxide and nitrogen, to the chamber to form a silicon nitride layer or a silicon oxynitride layer on the first surface of the silicon substrate to be a gate. Next, we transmit the second reaction gas, which comprises the oxygen and the hydrogen, to the chamber and make the second reaction gas to be dissociated into the oxygen radicals and the hydroxyl radicals. The oxygen radicals enter to the contacting surface between the silicon substrate and the silicon oxynitride layer by diffusing ways and pass through the post anneal process to form an interface on the contacting surface between the gate dielectric layer and the silicon substrate to produce the smaller volume of the semiconductor devices.

### BACKGROUND OF THE INVENTION

1. Field of the Invention

This invention relates to a method for making the gate dielectric layer, more particularly, to the method for making the interface between the gate dielectric layer and the silicon substrate by using oxygen radicals (O^{*}) and hydroxyl radicals (OH^{*})to decrease the defect density inside of the gate dielectric layer and to favor the semiconductor devices whose volume is decreased.

2. Description of the Prior Art

There is a great demand for shrinking semiconductor devices to provide an increased density of devices on the semiconductor chip that are faster and consume less power. The scaling of the devices in the lateral dimension requires vertical scaling as well so as to achieve adequate device performance. This vertical scaling requires the thickness of the gate dielectric to be reduced so as to provide the required device performance. However, thinning of the gate dielectric provides a smaller barrier to dopant diffusion from a polysilicon gate structure or metal diffusion from a metal gate structure and through the underlying dielectric and it may result in devices with diminished electrical performance and reliability.

One means of reducing these problems is to use silicon nitride as the gate dielectric layer. Silicon nitride has a higher dielectric constant than typical thermal grown silica (SiO₂) films and it provides greater resistance to impurity diffusion. However, the electrical properties of standard deposited silicon nitride films are far inferior to thermal oxides. Hence, to make the conventional silicon nitride film useful as a gate insulator, an oxide layer must be formed between the nitride layer and the substrate.

Silicon dioxide is typically used for gate oxides due to the fact that it can be relatively easily formed and has well known properties and a high quality interface with silicon. However, as devices continue to be scaled to smaller dimensions, the thickness of a silicon dioxide layer becomes too small to make a robust gate dielectric film. Therefore nitride and nitride-like layers are being examined because they have higher dielectric constants compared to silicon dioxide. However, problems can occur when forming the nitride compounds. More specifically, conventional low pressure chemical vapor deposition (LPCVD) depositions of silicon nitride form a layer that has a relatively high amount of electron traps due to a low nitrogen to silicon atomic ratio and a high hydrogen content. Conventional LPCVD are lengthy processes because of a low deposition rate coupled with lengthy heat up and cool down times. Additionally, conventional LPCVD processing may have adverse effects on the electrical characteristics of the device being formed.

The traditional method for making an interface layer between the gate dielectric layer and the silicon substrate is using the thermal oxidation to form a silicon oxide layer on the silicon substrate. We usually form a silicon dioxide layer on the silicon substrate. Then we deposit a nitride layer on the silicon oxide layer to be the gate dielectric layer. The silicon oxide layer is the interface layer between the nitride layer and the silicon substrate and makes the combination of the nitride layer and the silicon substrate stronger. However, after we reduce the dimension ratio of the semiconductor devices, the silicon dielectric layer, which is formed by using the thermal oxidation, will not fit in with the working environment when the devices are working and will reduce the efficiency of the semiconductor devices. Especially when the thickness of the semiconductor devices is lower than 30 angstroms, the efficiency of the semiconductor devices will be lost more seriously and will occur the conditions in the electric current leakage and the boron penetrating. Therefore, it is an important technology to form an oxide layer between the nitride layer and the silicon substrate without using the thermal oxidation.

### SUMMARY OF THE INVENTION

In accordance with the above-mentioned invention backgrounds, the silicon oxide layer, which is formed between the nitride layer and the silicon substrate by using the traditional thermal oxidation, cannot be used in the working environment in the smaller semiconductor devices. The main object of the present invention is to provide a method to form a interface layer between the silicon substrate and the nitride layer in the post anneal process by using the oxygen radicals and the hydroxyl radicals. The interface layer can be applied smoothly in the reduced dimension rate semiconductor devices.

The second object of this invention is to reduce the volume of the semiconductor devices successfully by using the oxygen radical and the hydroxyl radical to form a interface layer, which can be used smoothly, between the silicon substrate and the nitride layer in the post anneal process.

The third object of this invention is to decrease the proceeding time of the process and to increase the efficiency of the process by using the oxygen radical and the hydroxyl radical to form a interface layer between the silicon substrate and the nitride layer in the post anneal process.

The fourth object of this invention is to reduce the defect density of the gate dielectric layer by using the oxygen radical and the hydroxyl radical to form an interface layer between the silicon substrate and the nitride layer in the post anneal process.

The fifth object of this invention is to reduce the conditions in trapping the electron in the interface layer by using the oxygen radical and the hydroxyl radical to form a interface layer between the silicon substrate and the nitride layer in the post anneal process.

It is a further object of this invention is to raise the qualities of the semiconductor devices after the volume of the semiconductor devices to be decreased by using the oxygen radical and the hydroxyl radical to form a interface layer between the silicon substrate and the nitride layer in the post anneal process.

In according to the foregoing objects, The present invention provide a method to make the interface layer to be applied smoothly in the reduced dimension rate semiconductor devices by using the oxygen radical and the hydroxyl radical to form a interface layer between the silicon substrate and the nitride layer in the post anneal process. And the method can reduce the volume of the semiconductor devices according to the ratio to increase the density of the semiconductor devices on the wafer. Furthermore, the method can also raise the qualities of the semiconductor devices after the volume of the semiconductor devices to be decreased and decrease the proceeding time of the process to increase the efficiency of the process.

### BRIEF DESCRIPTION OF THE DRAWINGS

In the accompanying drawing forming a material part of this description, there is shown:

FIG. 1A shows a diagram in transmitting the mixed gas, which comprises the nitric monoxide and the nitrogen, to the chamber by using the method of the present invention;

FIG. 1B shows a diagram in transmitting the mixed gas, which comprises the oxygen and the nitric monoxide, to the chamber by using the method of the present invention;

FIG. 1C shows a diagram in forming a silicon oxynitride layer on the first surface of the substrate by using the method of the present invention;

FIG. 2A shows a diagram in transmitting the mixed gas, which comprises the oxygen and the hydrogen, to the chamber by using the method of the present invention;

FIG. 2B shows a diagram of the oxygen radical and hydroxyl radical diffuse into the interface between the silicon substrate and the silicon oxynitride layer by using the method of the present invention;

FIG. 2C shows a diagram in forming a silicon dioxide layer between the silicon substrate and the silicon oxynitride layer by using the method of the present invention;

FIG. 3 shows a flow chart in forming a silicon dioxide layer between the silicon substrate and the silicon oxynitride layer by using the method of the present invention;

### DESCRIPTION OF THE PREFERRED EMBODIMENT

The foregoing aspects and many of the attendant advantages of this invention will become more readily appreciated as the same becomes better understood by reference to the following detailed description, when taken in conjunction with the accompanying drawings, wherein:

In the present semiconductor device process, we usually use the nitride to be the material of the gate dielectric layer. However, the contacting surface between the silicon substrate and the nitride is not perfect. The contacting surface between the silicon substrate and the nitride usually comprises a micro-amount of nitrogen atoms to occur the condition in trapping electrons easily and to raise the defect density of the contacting surface. The traditional method in solving the problem is to form a silicon dioxide layer on the substrate by using thermal oxidation at first. Then the nitride is deposited on the silicon dioxide layer. The silicon dioxide layer, which is formed by thermal oxidation, is used to be a contacting surface between the silicon substrate and the nitride layer. However, the properties of the silicon dioxide cannot attain the requests after the volume of the semiconductor device is decreased. And we need to spend a lot of time on forming the silicon dioxide layer by using the traditional thermal oxidation and forming the nitride layer in the LPCVD process. Therefore, we must use the present invention to form the interface, between the silicon substrate and the nitride layer to reduce the volume of the semiconductor device successfully. Then the properties of the semiconductor device and. the efficiency of the semiconductor process will be raised.

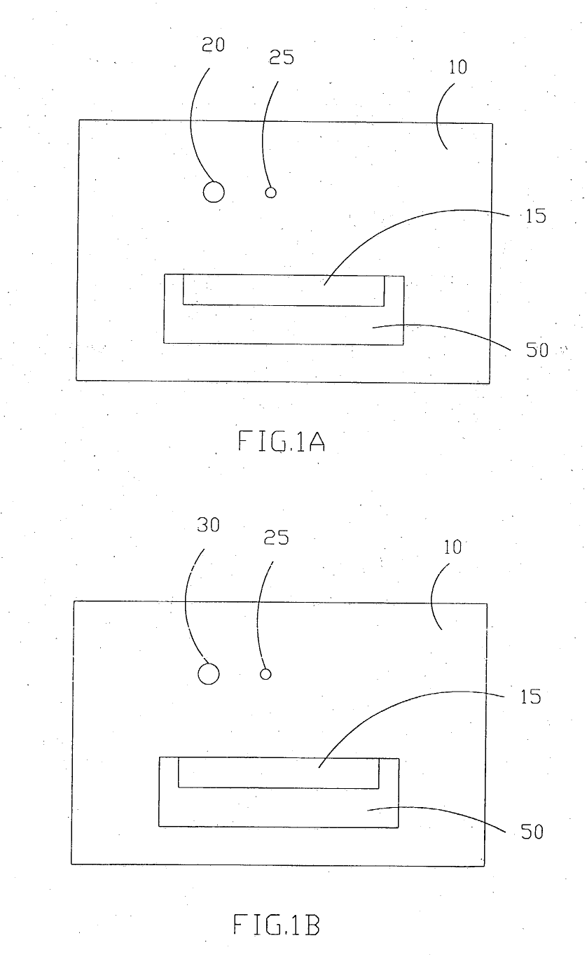

FIG. 1A to FIG. 1C show the first step diagrams in forming a silicon dioxide layer between the silicon substrate and the oxynitride layer by using the method of the present invention. Referring to FIG. 1A, we send the wafer 50, which has passed through the cleaning process to form a silicon substrate 15, to the chamber 10 at first. After the chamber 10 is closed, we start to raise the temperature inside of the chamber 10. When the temperature inside of the chamber gets the set temperature, we start to transmit the first reaction gas. The temperature inside of the chamber is about 600° C. to 1200° C. and the pressure inside of the chamber is about 1 to 900 torrs at this time. The first reaction gas is a mixed, which comprises the nitric monoxide 20 and the nitrogen 25 or comprises the oxygen 30 and the nitric monoxide 20 (referring to FIG. 1B). The ratio of the nitric monoxide 20 to nitrogen 25 is about 1:0 or 1:1000 to 1000:1 and the ratio of the oxygen 30 to the nitric monoxide 20 is about 1:1000 to 1000:1. In the common condition, we usually use the mixed gas, which comprises the nitric monoxide 20 and the nitrogen 25. When we want to control the concentration of the nitric monoxide 20 exactly, we use the mixed gas, which comprises the oxygen 30 and the nitric monoxide 20. The adding oxygen 30 is used for diluting the concentration of the nitric monoxide 20. The object of transmitting the first reaction gas is to form a silicon oxynitride layer 40 on the first surface 45 of the silicon substrate 15 by using the first reaction gas reacting with the silicon substrate 15 to be the gate dielectric layer (referring to FIG. 1C). The time of the process is adjusted following the different needs of the products. We usually set about 10 to 60 seconds in the process. The preferred timing on the step of the process is about 30 seconds for the present proceeding process.

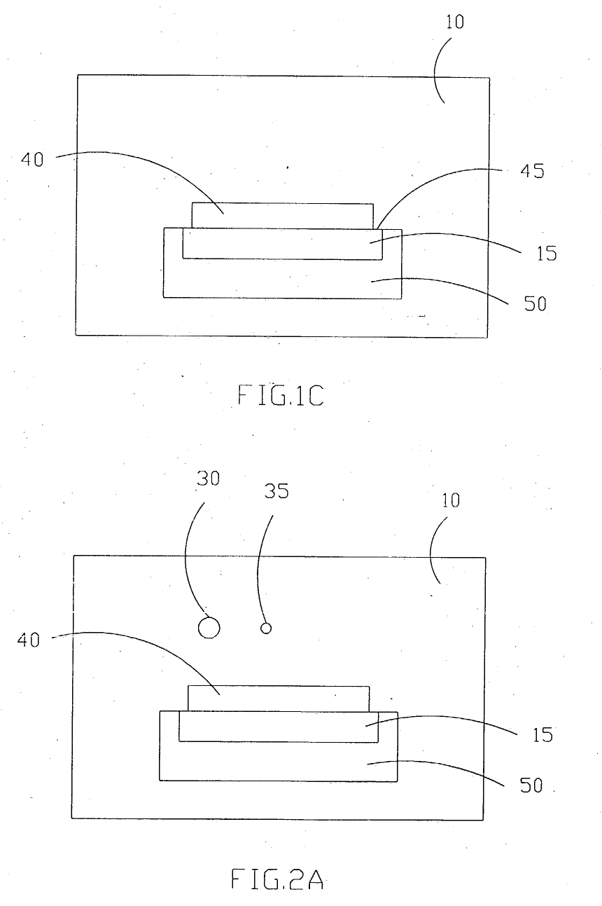

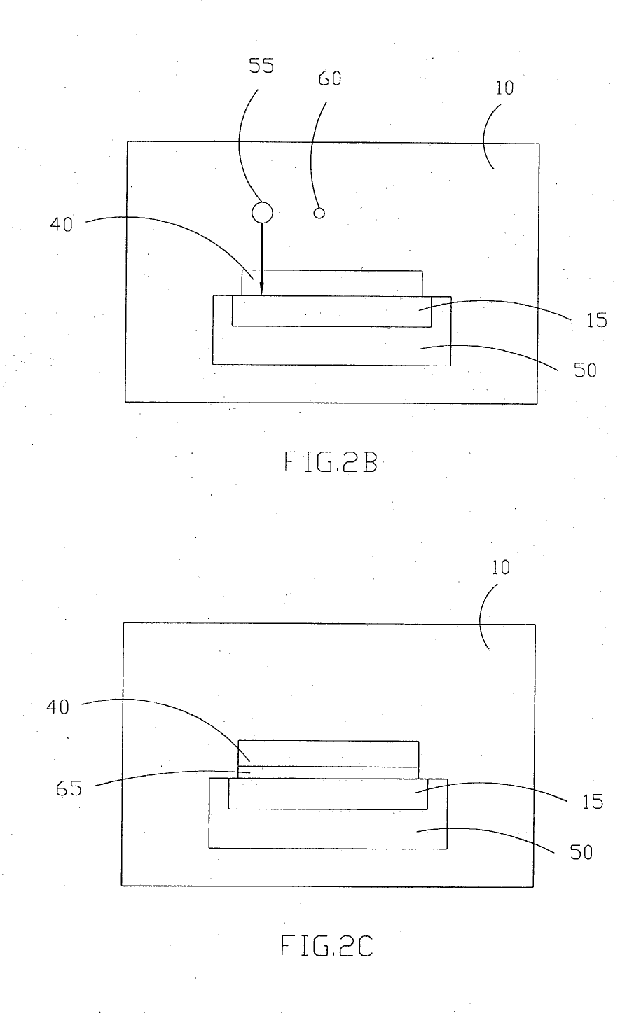

If the first reaction gas is a mixed, which comprises the nitric monoxide 20 and the nitrogen 25 or the mixed gas, which comprises the oxygen 30 and the nitric monoxide 20, after finishing the nitrogen process, we switch to the other chamber, or extract the remainder first reaction gas from the chamber immediately by using the air-extracting apparatus. Referring to FIG. 2A, then we adjust the pressure inside of the chamber to about 5 to 50 torrs. The pressure inside of the chamber is adjusted following the different needs of the products. We control the pressure inside of the chamber about at 10 torrs and the temperature inside of the chamber is still remained about 600 to 1200° C. The temperature is not adjusted because the velocity in raising or decreasing the temperature of the semiconductor apparatus is lower. If the temperature in the process is in the allowed range, we do not adjust the temperature inside of the chamber as far as possible to avoid extending the time of the process. When the pressure and the temperature inside of the chamber arrive at the requests, we can transmit the second reaction gas to the chamber 10 to proceed the reaction. The second reaction gas is a mixed gas, which comprises the oxygen 30 and the hydrogen 35. The ratio of the oxygen 30 to the hydrogen 35 is about 1:1000 to 1000:1. Referring to FIG. 2B, after the mixed gas, which comprises the oxygen and the hydrogen, is transmitted to the chamber, the mixed gas is dissociated in the oxygen radicals 55 and the hydroxyl radicals 60. The dissociated oxygen radicals 55 can be controlled to diffuse into the contacting surface between the silicon substrate 15 and the silicon oxynitride layer. Then we can proceed the post anneal process to the contacting surface by using the temperature and the pressure inside of the chamber 10. The post anneal process can make the oxygen radicals 55 to replace the seats of the nitrogen in the contacting surface between the silicon substrate 15 and the silicon oxynitride layer 40 successfully to form a silicon dioxide layer 65 on the contacting surface to be an interface (referring to FIG. 2C). The dissociated hydroxyl radicals 60 which can increase the reaction rate of the oxygen radicals 55 in the contacting surface between the silicon substrate and the silicon oxynitride layer as a catalyst. The transmitted oxygen 30 and hydrogen 35 also can be reacted to become the water. This process called the wet oxidation process. The time of the process is adjusted following the different needs of the products. We usually set about 5 to 50 seconds in the process. The preferred timing on the step of the process is about 10 seconds for the present proceeding process.

Finally, we transmit the third reaction gas to the chamber and decrease the temperature inside of the chamber. Then we complete the steps in forming the silicon dioxide layer to be the interface between the silicon substrate and the silicon oxynitride layer. The third reaction gas comprises the nitrogen to anneal the interface of the substrate.

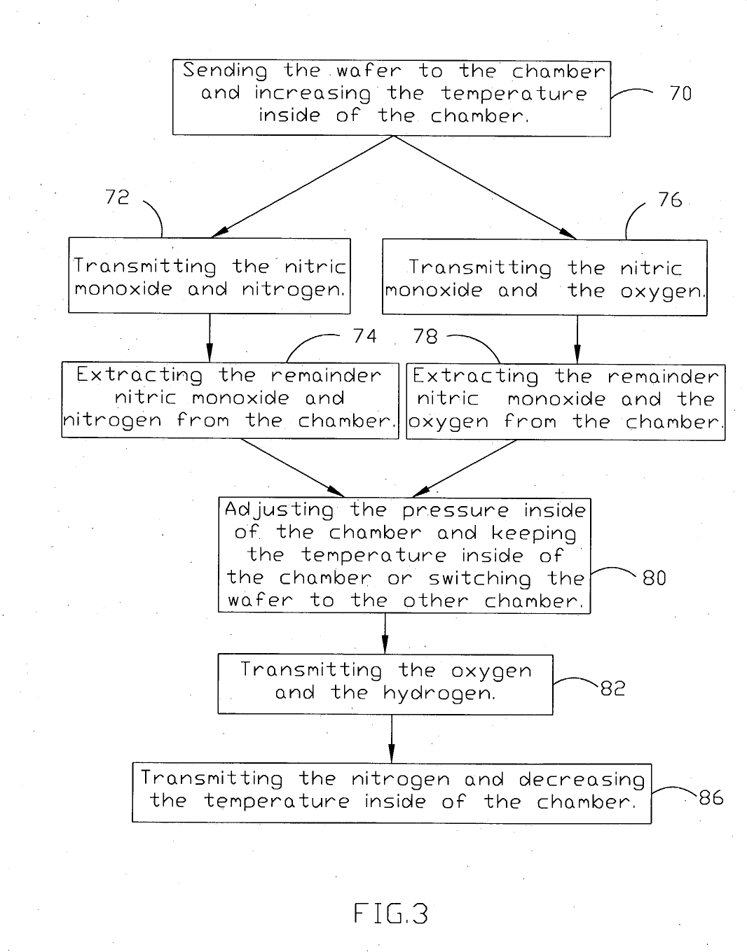

FIG. 3 shows a flow chart in forming a silicon dioxide layer between the silicon substrate and the silicon oxynitride layer by using the method of the present invention. First, we send the wafer, which has passed through the cleaning process for the silicon substrate, to the chamber and raise the temperature inside of the chamber (step 70). When the temperature inside of the chamber is about 600° C. to 1200° C., we transmit the first reaction gas. This first reaction gas is a mixed gas, which comprises the nitric monoxide and the oxygen (step 76) or comprises the nitric monoxide and nitrogen (step 72), to form the silicon oxynitride layer on the first surface of the silicon substrate of the wafer. The silicon oxynitride layer is used to be a gate dielectric layer. After the process passes through about 10 to 60 seconds, we stop to transmit the first reaction gas to the chamber and open the air-extracting apparatus to extract the remainder first reaction gas from the chamber (step 74 or step 78.) After the remainder first reaction gas is extracted from the chamber, we adjust the pressure inside of the chamber at once (step 80.) When the pressure inside of the chamber is about 5 to 50 torrs and the temperature inside of the chamber is held about 600° C. to 1200° C., we transmit the second reaction gas or switch to the other chamber. This second reaction gas is a mixed gas, which comprises the oxygen and the hydrogen (step 82), to form the silicon dioxide layer between the silicon substrate and the silicon oxynitride. The time of this process is about 5 to 50 seconds. After we finish this process, we stop to transmit the second reaction gas to the chamber immediately and transmit the third reaction gas (step 86), which comprises the nitrogen to anneal the interface of the substrate. Then we decrease the temperature inside of the chamber and finish the whole process.

The silicon dioxide layer, which is formed between the silicon substrate and silicon oxynitride layer, is not the pure silicon dioxide layer. There is micro-amount of the nitrogen in the silicon dioxide layer. Therefore, the silicon dioxide layer not only suit the working environment in the semiconductor devices after the volume of the semiconductor devices to be reduced but also reduce the conditions in the defect density and trapping electrons. When we use the traditional method to form the silicon dioxide layer between the silicon substrate and the silicon oxynitride layer to be an interface, we usually spend about 300 to 3000 seconds. If we use the method of the present invention, we only spend about 5 to 300 seconds. Proving from this, the method of the present invention for forming the silicon dioxide layer between the silicon substrate and the silicon oxynitride layer can increase the efficiency of the process and decrease the cost of the production.

In accordance with the present invention, we use the oxygen radicals and hydroxyl radicals, which are dissociated from the oxygen and the hydrogen to form the silicon dioxide layer on the contacting surface between the silicon substrate and the silicon oxynitride layer. The silicon dioxide layer can keep the normal capabilities after the volume of the semiconductor devices is reduced. The electric property of the silicon dioxide layer is better. Furthermore, the silicon dioxide can reduce the conditions in the defect density and trapping electrons and can decrease the bad rate of the wafers. Comparing the traditional method with the method of the present invention, the method of the present invention even more can raise the rate of the process and can decrease the cost of the production.

Although specific embodiments have been illustrated and described, it will be obvious to those skilled in the art that various modifications may be made without departing from what is intended to be limited solely by the appended claims.

What is claimed is:

1. A method for making a gate dielectric layer, said method comprises:
sending a wafer to a chamber;
adjusting a temperature inside of said chamber;
transmitting a first reaction gas to said chamber, said first reaction gas comprising a nitric monoxide and a nitrogen;
extracting said remainder first reaction gas from said chamber;
adjusting a pressure inside of said chamber and keeping said temperature inside of said chamber;
transmitting a second reaction gas to said chamber, said second reaction gas comprising a oxygen and a hydrogen;
extracting said remainder second reaction gas from said chamber;
transmitting a third reaction gas; and
decreasing said temperature inside of said chamber.

2. The method according to claim 1, wherein said wafer comprises a silicon substrate.

3. The method according to claim 1, wherein said temperature is about 600° C. to 1200° C.

4. The method according to claim 1, wherein said first reaction gas comprises a nitric monoxide and a oxygen.

5. The method according to claim 1, wherein said pressure is about 5 to 50 torrs.

6. The method according to claim 1, wherein timing in transmitting said first reaction gas is about 10 to 60 seconds.

7. The method according to claim 1, wherein said a timing in transmitting said second reaction gas is about 5 to 50 seconds.

8. The method according to claim 1, wherein said third reaction gas comprises a nitrogen.

9. The method according to claim 1, wherein said second reaction gas can be dissociated in a oxygen radical and a hydroxyl radical.

10. The method according to claim 9, wherein said second reaction gas can react to form a vapor.

11. A method for making a gate dielectric layer, said method comprises:
sending a wafer to a chamber, said wafer comprising a silicon substrate;
adjusting a temperature inside of said chamber;
transmitting a first reaction gas to said chamber, said first reaction gas comprising a nitric monoxide and a nitrogen;
forming a silicon oxynitride layer on a first surface of said silicon substrate;
extracting said remainder first reaction gas from said chamber;
adjusting a pressure inside of said chamber and keeping said temperature inside of said chamber;
transmitting a second reaction gas to said chamber, said second reaction gas can to be dissociated in a oxygen radical and a hydroxyl radical;
forming a silicon dioxide layer on a contacting surface between said silicon substrate and said silicon oxynitride layer;
extracting said remainder second reaction gas from said chamber;
transmitting a third reaction gas; and
decreasing said temperature inside of said chamber.

12. The method according to claim 11, wherein said temperature is about 600° C. to 1200°C.

13. The method according to claim 11, wherein said first reaction gas comprises a nitric monoxide and a oxygen.

14. The method according to claim 11, wherein said pressure is about 5 to 50 torrs.

15. The method according to claim 11, wherein a timing in transmitting said first reaction gas is about 10 to 60 seconds.

16. The method according to claim 11, wherein said a timing in transmitting said second reaction gas is about 5 to 50 seconds.

17. The method according to claim 11, wherein said second reaction gas comprises hydrogen and oxygen.

18. The method according to claim 17, wherein said second reaction gas can react to form a vapor.

19. The method according to claim 11, wherein said third reaction gas comprises a nitrogen.

20. The method according to claim 11, wherein said silicon dioxide layer comprises micro-amount of nitrogen radicals.
